(19) United States
(12) Patent Application Publication
(10) Pub. No.: US 2003/0090636 A1
(43) Pub. Date: May 15, 2003

(54) Anti-reflective coating on a photomask

(75) Inventor: Michal Mlejnek, Painted Post, NY (US)

Correspondence Address: WALL MARJAMA & BILINSKI, 101 SOUTH SALINA STREET, SUITE 400, SYRACUSE, NY, 13202, US

(73) Assignee: Corning, Inc.

(21) Appl. No.: 10/066,189

(22) Filed: Oct. 26, 2001

(51) Int. Cl. G03B 27/00; G03F 7/00

(52) U.S. Cl. 355/18; 430/311; 430/290; 355/77

(57) ABSTRACT

The present invention is directed to an optical device that includes an optically transparent mask blank that is characterized by a mask blank light transmission variation. An anti-reflective coating is disposed on the optically transparent component resulting in an optical device transmission variation that is less than the mask blank transmission variation. The present invention provides a simple solution to the problem of mitigating Fabry-Perot interference effects in a photomask. Disposing an anti-reflective coating on the light incident side of the photomask substantially reduces multiple reflections of the illuminating UV light. The illumination light propagates through the photomask only once. The AR coating also prevents any cumulative effects due to birefringence, surface roughness, or inhomogeneity.

### BACKGROUND OF THE INVENTION

1. Field of the Invention

The present invention relates generally to photolithography, and particularly to using antireflective coatings on photomasks to improve image quality.

2. Technical Background

Photolithography is often used to transfer patterns from photomasks onto semiconductor wafers to produce device features at predetermined locations on the wafer according to the circuit layout. Circuit features include transistors, gates, and interconnects. In MEMS devices, features include micro-mechanical devices such as cantilevered beams, latches, and other mechanical devices. In MOEMS devices, micro-optical devices such as mirrors have been developed. In any case, there is a need to increase the density of device features contained in semiconductor devices. Device designers are seeking to make device features smaller and reduce the amount of space between features. To accomplish this, the device features on photomasks have to become correspondingly smaller.

One phenomenon preventing the disposition of smaller features on photomasks is the Fabry-Perot Interference Effect. As shown in FIG. 1, the transmission (T) of illumination light through a photomask is dependent on the parameter φ. There are periodic variations in the intensity of the light as φ changes. The transmission ripple may result in uneven exposure of photoresist, linewidth variations, and lower illumination light intensity during exposure. One explanation is that the surfaces of the photomask blank are to a high degree plane-parallel. Thus, the mask blank approximates a Fabry-Perot plate. In the case of a coherent plane wave incident on a mask blank, the transmission can be written as:

T=1/(1+F sin²φ) (1)

wherein,

F sin²φ={4R/(1−R)²}*sin²[(2π/λ)cos θ(nL)+φ₀]. (2)

F is commonly referred to as the finesse factor. The Finesse factor F is largely dependent on R. R is a measure of the reflectivity of the two parallel plates in a Fabry-Perot interferometer. In this case, the plates are the plane parallel surfaces of the photomask blank. λ refers to the wavelength of the illumination variation (in the UV range in most lithography applications), θ is the angle between the propagation direction of the plane wave in the mask and the normal to the mask surfaces, and φ₀ is an arbitrary fixed constant. Since typical UV imaging systems employ monochromatic light, wavelength λ is fixed. Further, θ is also fixed at a specific angle, 0° for normal incidence, or ≈10° for annular illumination. Thus, the variables within φ are n and L. L is the thickness of the mask, and n is the refractive index of the mask material. ΔL relates to the surface roughness or the small tilt of the mask blank surfaces. ΔL can have a peak-valley difference of about 3.5 nm on a standard polished surface, and about 1.8 nm for a super polished surface. Δn refers to the birefringence of the photomask blank. What is needed is a method of mitigating Fabry-Perot interference effects in the photomask such that the transmission T is substantially constant at an optimum level.

### SUMMARY OF THE INVENTION

The present invention provides a simple solution to the problem of mitigating Fabry-Perot interference effects in a photomask. Disposing an AR coating on the light incident side of the photomask substantially reduces multiple reflections of the illuminating UV light. The illumination light propagates through the photomask only once. The AR coating also prevents any cumulative effects due to birefringence or inhomogeneity.

One aspect of the present invention is an optical device including an optically transparent component characterized by a component transmission variation. The component transmission variation is a function of at least one physical characteristic of the optically transparent component. A coating is disposed on a first side of the optically transparent component. The coating includes at least one layer of anti-reflective material such that the optical device transmission variation is less than the component transmission variation.

In another aspect, the present invention includes a photolithography system for making at least one semiconductor device. The system includes an illumination light source adapted to transmit illumination light characterized by a center wavelength. A projection optical system is optically coupled to the illumination light source. The projection optical system is configured to project the illumination light onto the at least one semiconductor device. A photomask is disposed between the illumination light source and the projection optical system. The photomask includes an optically transparent component and a coating disposed on a first side of the optically transparent component. The optically transparent component is characterized by a component transmission variation. The coating includes at least one layer of anti-reflective material such that a photomask transmission variation is less than the component light transmission variation.

In another aspect, the present invention includes a method for making an optical device. The method includes providing an optically transparent component characterized by a component light transmission variation. The component transmission variation is a function of at least one physical characteristic of the optically transparent component. A coating is disposed on a first side of the optically transparent component, the coating includes at least one layer of anti-reflective material such that the optical device transmission variation is less than the component transmission variation.

In another aspect, the present invention includes a method for making at least one semiconductor device using a photolithography system. The photolithography system includes an illumination light source adapted to transmit illumination light characterized by a center wavelength and a projection optical system optically coupled to the illumination light source. The projection optical system is configured to project the illumination light onto the at least one semiconductor device. The method includes the step of disposing a photomask between the illumination light source and the projection optical system. The photomask includes an optically transparent component and a coating disposed on at least a first side of the optically transparent component. The photomask also includes a pattern disposed on a second side of the component. The optically transparent component is characterized by a component transmission variation. The coating includes at least one layer of anti-reflective material such that a photomask transmission variation is less than the component transmission variation. The illumination light source is activated to thereby propagate illumination light through the photomask. The light is propagated through the photomask and projected from the projection optical system onto the at least one semiconductor device, whereby the pattern is transferred onto the semiconductor device.

Additional features and advantages of the invention will be set forth in the detailed description which follows, and in part will be readily apparent to those skilled in the art from that description or recognized by practicing the invention as described herein, including the detailed description which follows, the claims, as well as the appended drawings.

It is to be understood that both the foregoing general description and the following detailed description are merely exemplary of the invention, and are intended to provide an overview or framework for understanding the nature and character of the invention as it is claimed. The accompanying drawings are included to provide a further understanding of the invention, and are incorporated in and constitute a part of this specification. The drawings illustrate various embodiments of the invention, and together with the description serve to explain the principles and operation of the invention.

### BRIEF DESCRIPTION OF THE DRAWINGS

FIG. 1 is a chart showing the transmission (T) variation of illumination light through a photomask;

FIG. 2 is a perspective view of a photomask in accordance with a first embodiment of the present invention;

FIG. 3 is a perspective view of a photomask in accordance with a second embodiment of the present invention; and

FIG. 4 is a diagrammatic depiction of a photolithography system in accordance with a third embodiment of the present invention.

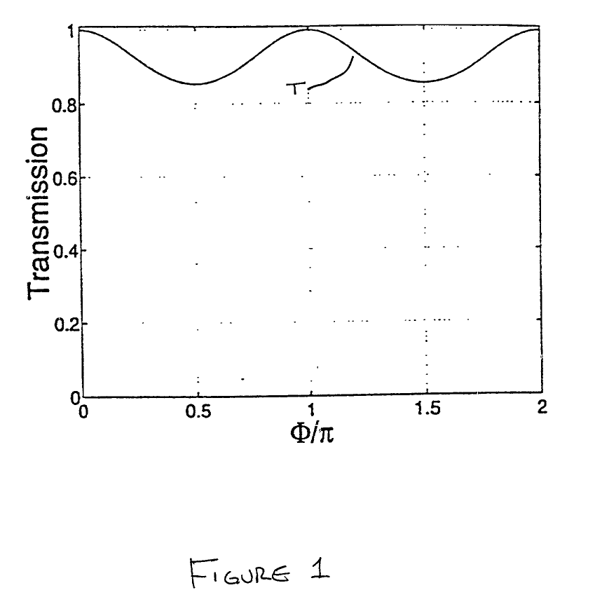

### DETAILED DESCRIPTION

Reference will now be made in detail to the present exemplary embodiments of the invention, examples of which are illustrated in the accompanying drawings. Wherever possible, the same reference numbers will be used throughout the drawings to refer to the same or like parts. An exemplary embodiment of the photomask of the present invention is shown in FIG. 2, and is designated generally throughout by reference numeral 10.

In accordance with the invention, the present invention for an optical device includes an optically transparent component characterized by a component light transmission variation. The component transmission variation is a function of at least one physical characteristic of the optically transparent component. A coating is disposed on a first side of the optically transparent component. The coating includes at least one layer of anti-reflective material such that the optical device transmission variation is less than the component transmission variation. The present invention provides a simple solution to the problem of mitigating Fabry-Perot interference effects in a photomask. Disposing an anti-reflective coating on the light incident side of the photomask substantially reduces multiple reflections of the illuminating UV light. The AR coating also prevents any cumulative effects due to birefringence, surface roughness, or inhomogeneity.

As embodied herein, and depicted in FIG. 2, a perspective view of photomask 10 in accordance with a first embodiment of the present invention is disclosed. Photomask 10 includes anti-reflection coating 12 disposed on optical blank 20. In the first embodiment, coating 12 includes one layer of MgF₂ anti-reflective material. In another embodiment, coating 12 includes a single layer of Al₂O₃ anti-reflective material. Optical blank 20 may be of any suitable type, but there is shown by way of example a fused silica mask blank. The mask blank may also be fabricated using. Those of ordinary skill in the art will also recognize that doped fused silica, synthetic quartz glass, calcium fluoride, or other doped glasses may be used as well, depending of course, on the application or desired effect. Those of ordinary skill in the art will recognize that the specifics of the AR coating, e.g., the number of layers, refractive index properties of each layer, or layer thicknesses, are a function of the operating wavelength and optical characteristics of the optical blank.

Table I and Table II show the results of theoretical calculations comparing transmission variation for mask blanks having differing glass parameters. These tables also show the transmission variation when an anti-reflective coating is disposed on the light incident side of the mask blank. In each of the Tables, each effect such as birefringence, homogeneity, thickness variation, or polish were considered separately.

TABLE II

| Data | | | | |
|---|---|---|---|---|
| calculated for 248 | | Transmission | | |
| nm, n(SiO₂ glass) | | Variation | | Transmission |
| ˜1.508, normal | Test Glass | (ΔΦ brackets) | | Variation (Test |
| incidence | parameters | (Test glass) | | glass w/AR coat) |
| Birefringence | −10 × 1.43 | 3.75% | (0.2536) | 0.61% |
| (nm/cm) | | | | |
| Homogeneity Δn | 8.857e−6 | 15% | (1.57) | 2.45% |
| Gross thickness | <0.041 | <15% | (<1.57) | <2.45% |
| variation across 6: | | | | |
| diameter (μm) | | | | |
| Polish III (P-V) (nm) | ˜16 × 2 surfaces | 13.5-14% | (1.223) | 2.27% |
| Polish IV (P-V (nm) | ˜8 × 2 surfaces | 8.5-9% | (0.6113) | 1.46% |

For example, the control glass experiences a 0.38% transmission variation for a birefringence of approximately 1×1.43 nm/cm. On the other hand the test glass experiences a 3.75% transmission variation for a birefringence of approximately 10×1.43 nm/cm. When coating 12 is disposed on the control glass, the transmission variation is reduced to 0.06%, about 16% of the value when no coating is employed.

TABLE I

| Data Calculated | | Transmission | Transmission |
|---|---|---|---|
| for 248 nm, n(SiO₂) glass) | | Variation | Variation |
| ˜1.508, Normal | Control Glass | (Φ in brackets) | (Control glass |
| incidence | Parameters | (Control Glass) | w/AR cost) |
| Birefringence (nm/cm) | ˜1 × 1.43 | 0.38% (0.0254) | 0.06% |
| Homogeneity n | 5.27e−6 | 11% (0.9358) | 1.78% |
| | (−3.69e−6 × 1.43) | | |
| Gross thickness variation | <5 | 15% (Multiple of | 2.45% |
| across 6: diameter (μm) | | 2π) | |
| Standard Polish (P-V) | ˜4 × 2 | 4.5% (0.3056) | 0.73% |
| (nm) | surfaces | | |
| Fine Polish (P-V) (nm) | ˜1 × 2 | 1.15% (0.0764) | 0.19% |
| | surfaces | | |

When coating 12 is disposed on the test glass, the transmission variation is reduced to 0.61%, about 16% of the value when no coating is employed. Thus, in each case, the transmission variation of an AR coated mask blank is reduced to less than one-sixth of the value of a uncoated blank. Similar transmission variation improvements are obtained for the other glass parameters.

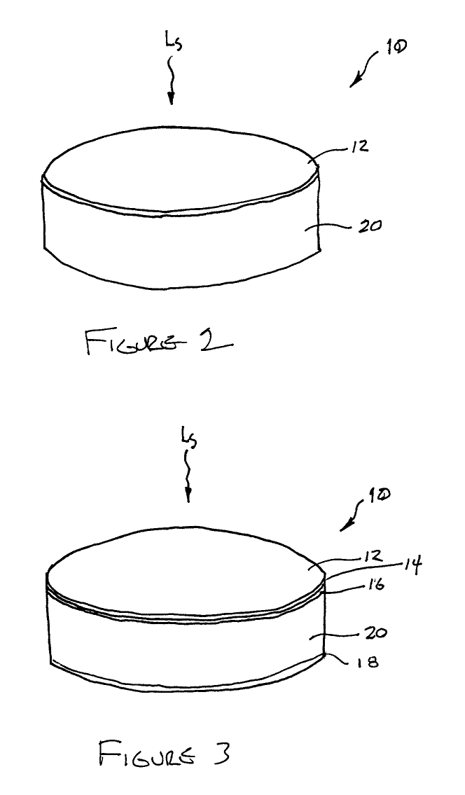

As embodied herein, and depicted in FIG. 3, a perspective view of a photomask in accordance with a second embodiment of the present invention is disclosed. Photomask 10 includes anti-reflection coating 12 disposed on optical blank 20. In the second embodiment, coating 12 includes multiple layers of anti-reflective material. Although layer 14 and layer 16 are depicted in FIG. 3, those of ordinary skill in the art will recognize that two or more layers of antireflective material having distinct refractive indices can be employed. Layer 18 is an optional AR coating. Thus, in one embodiment of the present invention photomask 10 includes AR coatings on both sides of blank 20.

### EXAMPLES

The invention will be further clarified by the following examples which are intended to be exemplary of the invention.

### Example 1

In this example mask blank 20 is fabricated using fused silica glass having a refractive index of 1.567 for incident light at approximately 190 nm. The reflectance of the upper portion of blank 20 without the antireflective coating is 4.88%. Coating 12 is implemented using a single layer of MgF₂ having a refractive index of approximately 1.43 for incident light at approximately 190 nm. The reflectance of the upper portion of blank 20 with the MgF₂ antireflective coating is 1.75%. This represents a reduction in reflectance of approximately 64%. As discussed above, reflectivity is the most significant factor causing transmission variation.

### Example 2

In this example mask blank 20 is fabricated using silica glass having a refractive index of 1.567 for incident light at approximately 190 nm. The reflectance of blank 20 without the antireflective coating is 4.88%. Coating 12 includes layer 14 and layer 16. Layer 14 includes a MgF₂ material having a refractive index of approximately 1.43 for incident light at approximately 190 nm. Layer 16 includes an Al₂O₃ material having a refractive index of approximately 1.834 for incident light at approximately 190 nm. The reflectance of the upper portion of blank 20 with the aforementioned layers is 0.59%. This represents a reduction in reflectance of approximately 86%.

### Example 3

In this example mask blank 20 is fabricated using silica glass having a refractive index of 1.508 for incident light at approximately 248 nm. The reflectance of the upper portion of blank 20 without the AR coating is 4.1%. Coating 12 is implemented using a single layer of MgF₂ having a refractive index of approximately 1.403 for incident light at approximately 248 nm. The reflectance of the upper portion of blank 20 with the MgF₂ AR coating is 1.75%. This represents a reduction in reflectance of approximately 57%.

### Example 4

In this example mask blank 20 is fabricated using silica glass having a refractive index of 1.508 for incident light at approximately 248 nm. The reflectance of the upper portion of blank 20 without the AR coating is 4.1%. Coating 12 included layer 14 and layer 16. Layer 14 includes a MgF₂ material having a refractive index of approximately 1.403 for incident light at approximately 248 nm. Layer 16 includes an Al₂O₃ material having a refractive index of approximately 1.834 for incident light at approximately 248 nm. The reflectance of the upper portion of blank 20 with the aforementioned layers is 0.39%. This represents a reduction in reflectance of approximately 90%.

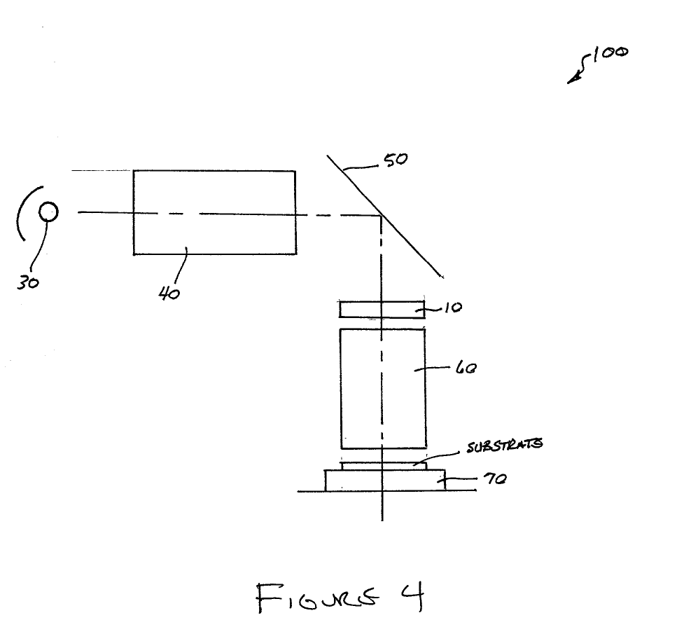

As embodied herein, and depicted in FIG. 4, a diagrammatic depiction of photolithography system 100 in accordance with a third embodiment of the present invention is disclosed. System 100 includes UV light source 30 coupled to illumination optical system 40. Illumination optical system 40 is optically coupled to photomask 10 by mirror 50. Photomask 10 of the present invention is coupled to the semiconductor substrate by projection optical system 60, which is configured to project device features disposed on photomask 10 onto the photoresist disposed on the semi-conductor wafer. The device pattern includes a metallic pattern corresponding to device features in a semiconductor device. Typically, the metallic pattern consists of a single layer of Cr₂O₃ disposed on blank 20. The semiconductor wafer is disposed on stage 70, which positions the semiconductor wafer in three-dimensional space relative to projection optical system 60.

The use of photomask 10 of the present invention provides a simple solution to the problem of mitigating Fabry-Perot interference effects. AR coating 12 on the light incident side of photomask 20 substantially reduces the reflection of the illuminating UV light. The AR coating also prevents any cumulative effects due to birefringence or inhomogeneity. Thus, the exposure of the photoresist disposed on the wafer is more uniform. Further, linewidth variations are substantially reduced. Finally, the effect of lower illumination light intensity due to transmission variation is mitigated.

It will be apparent to those skilled in the art that various modifications and variations can be made to the present invention without departing from the spirit and scope of the invention. Thus, it is intended that the present invention cover the modifications and variations of this invention provided they come within the scope of the appended claims and their equivalents.

What is claimed is:

1. An optical device comprising:
an optically transparent component characterized by a component light transmission variation, the component transmission variation being a function of at least one physical characteristic of the optically transparent component; and
an anti-reflective coating disposed on a first side of the optically transparent component, the anti-reflective coating including at least one layer of material such that the optical device transmission variation is less than the component transmission variation.

2. The optical device of claim 1, wherein the optical device transmission variation is equal to approximately one-sixth the component transmission variation.

3. The optical device of claim 1, wherein the at least one characteristic is birefringence.

4. The optical device of claim 1, wherein the at least one characteristic is refractive index inhomogeneity.

5. The optical device of claim 1, wherein the at least one characteristic is a thickness variation of the optically transparent component.

6. The optical device of claim 1, wherein the at least one layer includes Al2O3.

7. The optical device of claim 1, wherein the at least one layer includes MgF2.

8. The optical device of claim 1, wherein the anti-reflective coating includes a plurality of layers.

9. The optical device of claim 8, wherein the plurality of layers includes at least one layer comprising Al2O3.

10. The optical device of claim 8, wherein the plurality of layers includes at least one layer comprising MgF2.

11. The optical device of claim 1, wherein the optically transparent component is comprised of a glass material.

12. The optical device of claim 1, wherein the optically transparent component is comprised of silica.

13. The optical device of claim 12, wherein the optically transparent component is comprised of fused silica.

14. The optical device of claim 1, wherein the optically transparent component is comprised of quartz glass.

15. A photolithography system for making at least one semiconductor device, comprising:
an illumination light source adapted to transmit illumination light characterized by a center wavelength;
a projection optical system optically coupled to the illumination light source, the projection optical system being configured to project the illumination light onto the at least one semiconductor device; and
a photomask disposed between the illumination light source and the projection optical system, the photomask including an optically transparent component and a coating disposed on a first side of the optically transparent component, the optically transparent component being characterized by a component transmission variation, the coating including at least one layer of anti-reflective material such that a photomask transmission variation is less than the component light transmission variation.

16. The system of claim 15, wherein the photomask transmission variation is equal to approximately one-sixth the component transmission variation.

17. The system of claim 15, wherein the center wavelength is less than or equal to 250 nm.

18. The system of claim 15, wherein the center wavelength is substantially 248 nm.

19. The system of claim 15, wherein the wavelength is substantially 193 nm.

20. The system of claim 15, wherein the wavelength is substantially 157 nm.

21. The system of claim 15, wherein the at least one layer includes Al2O3.

22. The system of claim 15, wherein the at least one layer includes MgF2.

23. The system of claim 15, wherein the anti-reflective coating includes a plurality of layers.

24. The system of claim 23, wherein the plurality of layers includes at least one layer comprising Al2O3.

25. The system of claim 23, wherein the plurality of layers includes at least one layer comprising MgF2.

26. The system of claim 15, wherein the first side is a light incident side with respect to the illumination light source.

27. The system of claim 26, wherein the device pattern corresponds to an electronic circuit in a semiconductor device.

28. The system of claim 26, wherein the device pattern corresponds to a mechanical micro-structure in a MEMs device.

29. The system of claim 26, wherein the device pattern corresponds to an optical component.

30. A method for making an optical device, the method comprising:
providing an optically transparent component characterized by a component light transmission variation, the component transmission variation being a function of at least one physical characteristic of the optically transparent component; and
disposing a coating on a first side of the optically transparent component, the coating including at least one layer of anti-reflective material such that the optical device transmission variation is less than the component transmission variation.

31. The method of claim 30, wherein the at least one layer includes Al2O3.

32. The method of claim 30, wherein the at least one layer includes MgF2.

33. The method of claim 30, wherein the anti-reflection coating includes a plurality of layers.

34. The method of claim 33, wherein the plurality of layers includes at least one layer comprising Al2O3.

35. The method of claim 33, wherein the plurality of layers includes at least one layer comprising MgF2.

36. The method of claim 30, wherein the optically transparent component is comprised of a glass material.

37. The method of claim 30, wherein the optically transparent component is comprised of silica.

38. The method of claim 37, wherein the optically transparent component is comprised of fused silica.

39. The method of claim 30, wherein the optically transparent component is comprised of quartz glass.

40. method of claim 39, wherein the device pattern corresponds to an electronic circuit.

41. The method of claim 39, wherein the device pattern corresponds to a mechanical micro-structure in a MEMs device.

42. The method of claim 39, wherein the device pattern corresponds to an optical component.

43. A method for making at least one semiconductor device using a photolithography system, the photolithography system including an illumination light source adapted to transmit illumination light characterized by a center wavelength and a projection optical system optically coupled to the illumination light source, the projection optical system being configured to project the illumination light onto the at least one semiconductor device, the method comprising:
disposing a photomask between the illumination light source and the projection optical system, the photomask including an optically transparent component and a coating disposed on a first side of the optically transparent component, the photomask also including a pattern disposed on a second side of the component opposite the first side, the optically transparent component being characterized by a component transmission variation, the coating including at least one layer of anti-reflective material such that a photomask transmission variation is less than the component transmission variation;
activating the illumination light source being activated to thereby propagate illumination light through the photomask; and
projecting the light propagating through the photomask from the projection optical system onto the at least one semiconductor device, whereby the pattern is transferred onto the semiconductor device.

44. The method of claim 43, wherein the pattern corresponds to an electronic circuit.

45. The method of claim 43, wherein the pattern corresponds to a mechanical micro-structure in a MEMs device.

46. The method of claim 43, wherein the device pattern corresponds to an optical component.

47. The method of claim 43, wherein the at least one layer includes Al2O3.

48. The method of claim 43, wherein the at least one layer includes MgF2.

49. The method of claim 43, wherein the anti-reflection coating includes a plurality of layers.

50. The method of claim 43, wherein the plurality of layers includes at least one layer comprising Al2O3.

51. The method of claim 43, wherein the plurality of layers includes at least one layer comprising MgF2.

52. The method of claim 43, wherein the optically transparent component is comprised of a glass material.

53. The method of claim 43, wherein the optically transparent component is comprised of silica.

54. The method of claim 43, wherein the optically transparent component is comprised of fused silica.

55. The method of claim 43, wherein the optically transparent component is comprised of quartz glass.
